(19) United States
(12) Patent Application Publication
(10) Pub. No.: US 2011/0317536 A1
(43) Pub. Date: Dec. 29, 2011

(54) CURRENT DRIVING CIRCUIT AND LIGHT STORAGE SYSTEM HAVING THE SAME

(75) Inventors: Sang Hyun CHA, Yongin-si (KR); Deuk Hee PARK, Seoul (KR); Jae Shin LEE, Gyeonggi-do (KR)

(73) Assignee: SAMSUNG ELECTRO-MECHANICS CO., LTD., Gyunggi-do (KR)

(21) Appl. No.: 12/915,537

(22) Filed: Oct. 29, 2010

(30) Foreign Application Priority Data
Jun. 24, 2010 (KR) 10-2010-0060072

(51) Int. Cl. G11B 7/00; H03K 3/00

(52) U.S. Cl. 369/100; 327/109

(57) ABSTRACT

Disclosed herein are a current driving circuit and a light storage system having the same. The current driving circuit includes a plurality of channel circuits that include a first transistor into which the input current flows, a second transistor generating the output current by mirroring the input current, a plurality of switches connected between the first and second transistors in parallel and optionally electrically connecting the first and second transistors in response to the control signals, a controller optionally activating the control signals each corresponding to the switches according to the magnitude of the input current; and an adder that adds output currents of the channel circuits to generate driving current. The current driving circuit can stably supply the driving current while preventing a delay in the driving current.

### CROSS REFERENCE TO RELATED APPLICATION

This application claims the benefit of Korean Patent Application No. 10-2010-0060072, filed on Jun. 24, 2010, entitled “Current Driving Circuit And Light Storage System Having The Same,” which is hereby incorporated by reference in its entirety into this application.

### BACKGROUND OF THE INVENTION

1. Technical Field

The present invention relates to a current driving circuit and a light storage system having the same, and more particularly, to a current driving circuit capable of stably driving output current regardless of the change in input current and a light storage system having the same.

2. Description of the Related Art

Recently, an optical disc having larger storage capacity and stronger durability has been widely used as a next-generation storage medium, instead of storage media such as a magnetic tape or a magnetic disc, or the like, that have been widely used in the related art. An example of the optical disc may include a compact disc (CD), a digital video disc (DVD), a Blue-Ray, or the like.

A light storage system is an apparatus that records information on an optical disc or reads the recorded information by using laser light. First, when recording information on the optical disc, a strong laser beam is irradiated on the surface of the optical disc to generate fine holes, thereby recording the information in the holes. Meanwhile, when reading information recorded in the optical disc, a laser beam with a weak intensity is irradiated on the surface of the optical disc and is reflected therefrom. Thereafter, the reflected beam is detected through a photodiode and is converted into an electrical signal, thereby reproducing the information.

Generally, in the light storage system, a laser diode emitting laser light receives a driving current generated from a current driving circuit to vary the intensity of light. Therefore, in the light storage system, it is important for the current driving circuit to stably supply the driving current at an accurate timing. When the driving current is not stably supplied, the intensity of light from the laser diode is changed, such that a problem is generated in recording and detecting the information.

### SUMMARY OF THE INVENTION

An object of the present invention is to provide an apparatus capable of stably driving output current regardless of the change in magnitude of input current.

According to an exemplary embodiment of the present invention, there is provided a current driving circuit, including: a plurality of channel circuits that include a first transistor into which the input current flows, a second transistor generating the output current by mirroring the input current, a plurality of switches connected between the first and second transistors in parallel and optionally connecting electrically the first and second transistors in response to the control signals, and a controller optionally activating the control signals each corresponding to the switches according to the magnitude of the input current; an adder that adds output current of the channel circuits to generate driving current.

According to another exemplary embodiment of the present invention, there is provided a light storage system, including: a current driving circuit including a plurality of channel circuits that include a first transistor into which the input current flows, a second transistor generating the output current by mirroring the input current, a plurality of switches connected between the first and second transistors in parallel and optionally connecting electrically the first and second transistors by the control signals and optionally activates the switches according to the magnitude of the input current, and adds output current from the channel circuits and outputs them to the driving current; and an optical pickup unit that emits light to an optical disc to record information on the optical disc or detect the recorded information and controls the intensity of light according to the driving current.

### BRIEF DESCRIPTION OF THE DRAWINGS

FIG. 1 is a block diagram showing a configuration of a current driving circuit according to an exemplary embodiment of the present invention;

FIG. 2 is a circuit diagram showing a configuration of a second channel circuit of FIG. 1; and

FIG. 3 is a block diagram showing an example of a configuration of a light storage system including a current driving circuit of FIG.

1.

### DESCRIPTION OF THE PREFERRED EMBODIMENTS

Hereinafter, exemplary embodiments of the present invention will be described with reference to the accompanying drawings. However, the invention may be embedded in many different forms and should not be construed as limited to the embodiments set forth herein.

In the following description, when it is determined that the detailed description of the conventional technology related to the present invention would confuse the gist of the present invention, such a description may be omitted. Terms used in the specification and claims herein are defined by considering the functions thereof in the present invention so that they may be varied according to a user's and an operator's intentions or practices. Therefore, the definitions thereof should be construed based on the contents throughout the specification.

As a result, the spirit of the present invention is determined by the claims and the following exemplary embodiments may be provided to efficiently describe the spirit of the present invention to those skilled in the art.

Hereinafter, a current driving circuit and a light storage system according to exemplary embodiments of the present invention will be described with reference to the accompanying drawings.

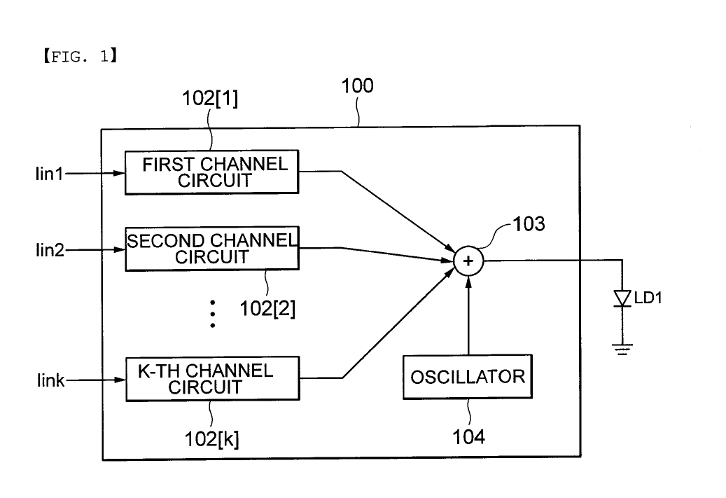

FIG. 1 is a block diagram showing a configuration of a current driving circuit according to an exemplary embodiment of the present invention.

The current driving circuit 100 according to an exemplary embodiment of the present invention includes a plurality of channel circuits 102 [1:k], an adder 130, and an oscillator 104, as shown in FIG. 1.

The functions of each block in the current driving circuit 100 configured as described above will now be described.

First, the channel circuits 102 [1:k] receive input current Iin1 to IinK, respectively, and amplify and output them. A first channel circuit 102 [1] among the channel circuits 102 [1:k] generates smaller output current than other channel circuits 102 [2:k] so that a laser diode LD1 irradiates a weak laser beam when the light storage system detects information recorded in the optical disk. Meanwhile, second to k-th channel circuits 102 [2:k] generate larger output current than the first channel circuit 102 [1] so that the laser diode LD1 irradiates the strong laser beam when the light storage system records the information in the optical disc. The second to k-th channel circuits 102 [2:k] supply output current having different magnitudes and are optionally activated, thereby making it possible to combine the output current at various magnitudes. The adder 103 adds the output current supplied from the channel circuits 102 [1:k]. Therefore, the laser diode LD1 emits light with various intensities according to the driving current with various magnitudes.

Meanwhile, an oscillator 104 oscillates a predetermined high frequency current. Therefore, the driving current generated from the adder 103 has a form of adding the AC high frequency current of the oscillator 104 to the DC output current of the channel circuits 102 [1:k]. In this case, the reason for generating the driving current by adding the AC high frequency current in the adder 103 is to remove the interference phenomenon between the light emitted from the laser diode LD1 and the light reflected from the optical disc.

As described above, the current driving circuit 100 adds the DC output currents of several channel circuits 102 [1:k] to the AC high frequency current of the oscillator 104 to generate the driving current for driving the laser diode LD1.

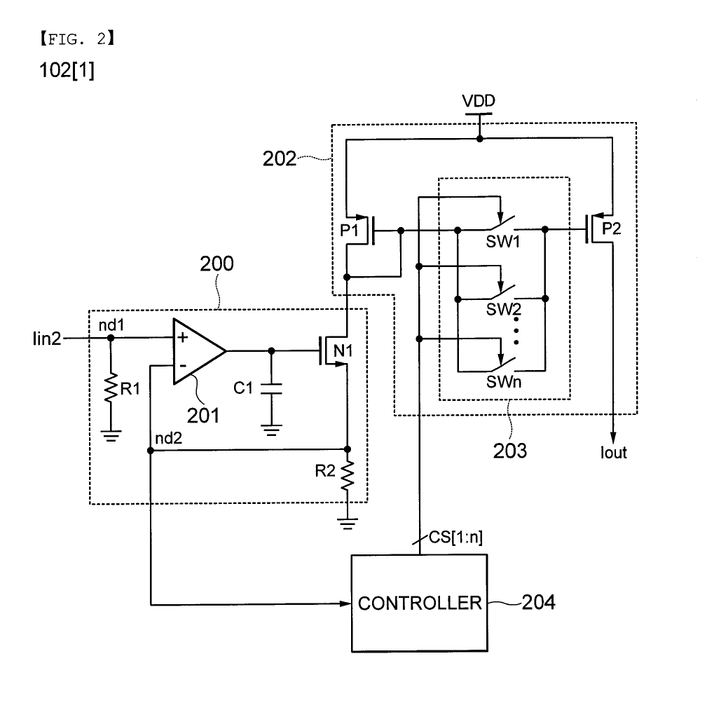

FIG. 2 is a circuit diagram showing a configuration of a first channel circuit of FIG. 1.

The second channel circuit 102 [2] includes a voltage-to-current converter 200, a current mirror circuit 202, and a controller 204, as shown in FIG. 2.

First, the voltage-to-current converter 200 receives input current Iin2 to generate current having the same magnitude as the input current by voltage-to-current conversion. In more detail, when input current Iin2 is applied to the voltage-to-current converter 200, input voltage is formed at a node nd1 and a feedback voltage is formed at a node nd2. In this case, a differential amplifier 201 continuously compares the input voltage with the feedback voltage to supply current to the node nd2 by controlling a channel of an NMOS transistor N1 until two voltage levels become the same. Therefore, after a predetermined time elapses, the node current flowing into the node nd2 is identical with the input current Iin2.

Next, the current mirror circuit 202 includes PMOS transistors P1 and P2 and a switch unit 203 including a plurality of switches SW1 to SWn.

Switches S21 to S2n in the switch unit 203 are connected in parallel between the PMOS transistor P1 and the PMOS transistor P2. The switches are optionally turned-on in response to the control signals CS [1:n] to electrically connect the PMOS transistor P1 to the PMOS transistor P2, thereby activating the mirroring of the current mirror circuit 202. In this case, the PMOS transistor P2 mirrors the input current Iin2 flowing into the PMOS transistor P1 to generate output current lout. That is, the switches SW1 to SWn controlling the PMOS transistor P2 mirroring the input current Iin2 are optionally turned-on. Meanwhile, the channel size of the PMOS transistor P1 and the channel size of the PMOS transistor P2 are set to be a ratio of 1:M, such that the output current lout has a size M times larger than the input current Iin2. Herein, the channel size represents the width (W)/length (L) of the channel. The switches SW1 to SWn may be set to have different channel sizes and to have the same channel size. Meanwhile, the switches SW1 to SWn may be constituted by a MOS transistor (MOSFET).

Next, the controller 204 senses the node current generated at the node nd2 of the voltage-to-current converter 200 to optionally activate a plurality of control signals CS [1:n] according to the magnitude of the node current. In this case, since the node current is the same as the input current Iin2, the same effect can be obtained even when the controller 204 senses the input current Iin2.

The controller 204 is differently operated according to the case where the switches SW1 to SWn of the current mirror circuit 202 have different channel sizes and the case where they are the same channel size.

First, when the switches SW1 to SWn have different channel sizes, the controller 204 optionally activates any one of the plurality of control signals CS [1:n] according to the magnitude of the input current Iin2. In this case, even in the case of the switches SW1 to SWn, only one switch is turned-on corresponding to the activated control signals. In more detail, the controller 204 activates the control signal corresponding to the switch having a larger channel size when the magnitude of the input current Iin2 is large and activates the control signals corresponding to the switch having a smaller channel size when the magnitude of the input current Iin2 is small. That is, as the magnitude of the input current Iin2 becomes large, the switch having a larger channel size is turned-on.

Next, when the switches SW1 to SWn have the same channel sizes, the controller 204 optionally activates at least one of the plurality of control signals CS [1:n] according to the magnitude of the input current Iin2. In this case, even in the case of the switches SW1 to SWn, at least one switch is turned-on corresponding to the activated control signals. In more detail, the controller 204 activates a larger number of control signals CS [1:n] when the magnitude of the input current Iin2 is large to turn-on a larger number of switches SW1 to SWn and when the magnitude of the input current Iin2 is small, activates a smaller number of control signals CS [1: n] to turn-on a smaller number of switches SW1 to SWn. That is, as the magnitude of the input current Iin2 becomes large, the number of switches turned-on between the PMOS transistors P1 and P2 is increased, thereby increasing the total channel size. On the other hand, as the size of the input current Iin2 becomes small, the number of switches turned-on between the PMOS transistors P1 and P2 is reduced, thereby reducing the total channel size.

The controller 204 senses the input current Iin2 in an analog form to output the control signals CS [1:n] in a digital form and therefore, may use the analog-to-digital converter.

Meanwhile, unlike the exemplary embodiment of the present invention, when a single switch is connected between the PMOS transistors P1 and P2, the channel size between the PMOS transistors P1 and P2 is fixed regardless of the change in the magnitude of the input current Iin2, thereby leading to the problem in the operation of the current circuit mirror 202. For example, the case where the input current is large but the channel size of the switch is small and the case where the input current is small but the channel size of the switch is large will now be described.

The case where the input current is large but the channel size of the switch is small will first be described.

As the channel size of the switch is small, the turn-on resistance is increased. In this case, the time constant of the switch is also large, such that the waveform of the output current lout output through the PMOS transistor P2 is increased, thereby increasing the rising time. When these problems occur in a part or all of the channel circuits, the driving current of the current driving circuit generated by adding the output current of the channel circuits may be delayed. As a result, the operating timing of the element or apparatus operated by receiving the driving current may be delayed.

Next, the case where the input current is small but the channel size of the switch is large will be described.

As the channel size of the switch becomes large, the parasitic capacitance becomes large. That is, when the remaining charge is increased in the switch and the PMOS transistor P2 drives the small output current, a glitch may occur in the output current due to the charge injection phenomenon. In this case, the setting time when the output current is stabilized at a desired level becomes long. When the problems occur in a part or all of the channel circuits, the driving current of the current driving circuit is unstabilized for a predetermined time since the setting time is long. Therefore, the operation of the element or apparatus operated by receiving the driving current may be unstabilited for a predetermined time. In this case, the glitch is referred to as a noise pulse generated in an unnecessary period.

However, as in the exemplary embodiment of the present invention, when the channel size of the switch connecting between the PMOS transistors P1 and P2 of the current mirror circuit 202 is controlled according to the size of the input current Iin2, the increase in the rising time and the setting time of the output current lout that can be generated according to the change in the input current Iin2 may be reduced.

Meanwhile, in FIG. 2, the PMOS transistors P1 and P2 may be replaced with the NMOS transistors and the direction of the output current lout may be changed. That is, the polarity and current direction of the transistors shown in FIG. 2 are shown by way of example.

Meanwhile, all of the channel circuits 102 [1:k] of FIG. 1 have the same configuration and therefore, the description of the remaining channel circuits will be described.

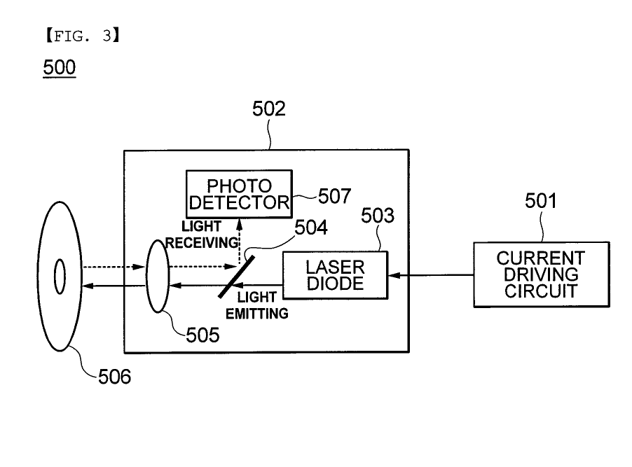

FIG. 3 is a block diagram showing an example of a configuration of a light storage system including a current driving circuit of FIG. 1.

Referring to FIG. 3, a light storage system 500 includes a current driving circuit 501 and an optical pickup unit 502.

Although the current driving circuit 501 is described in detail with reference to FIGS. 1 and 2, it includes a plurality of channel circuits that includes a first transistor into which the input current flows, a second transistor generating the output current by mirroring the input current, a plurality of switches connected between the first and second transistors in parallel and optionally connecting electrically the first and second transistors in response to the control signals, a controller optionally activating the control signals each corresponding to the switches according to the magnitude of the input current. In addition, the current driving circuit 501 includes an adder that generates the driving current by adding the output current of the channel circuits. By this configuration, the current driving circuit 501 stably drives the output current regardless of the change in the input current and adds the output current to stably output the driving current.

Meanwhile, the optical pickup unit 502 includes a laser diode 503, a beam splitter 504, an objective lens 505, and a photo detector 507.

The optical pickup unit 502 irradiates the strong laser light on an optical disc 506 to generate holes on the surface of the optical disc, thereby recording the information in the holes or irradiates the weak laser light to detect light reflected from the surface of the optical disc, thereby obtaining the recorded information. The method of obtaining the information recorded on the optical disc will now be described.

The laser diode 503 stably receives the driving current from the current driving circuit 501 to emit light. The light emitted by the laser diode 503 is focused on the objective lens 505 through the beam splitter 504 and reaches the surface of the optical disc. The light is reflected from the surface of the optical disc and the moving direction of the reflected light is changed by the beam splitter 504. In this case, the photo detector 507 receives the reflected light to convert the optical signals into the electrical signals. The light storage system 500 obtains the information recorded in the optical disc from the electrical signals. Meanwhile, the photo detector 507 may be constituted by a photo diode that is a light receiving device.

The exemplary embodiments can vary the channel size of the switch controlling the transistor mirroring the current in the current mirror circuit according to the magnitude of the input current to prevent the rising time and setting time of the output current from being increased and stably drive the output current regardless of the change in the input current.

Although the exemplary embodiments of the present invention have been disclosed for illustrative purposes, those skilled in the art will appreciate that various modifications, additions and substitutions are possible, without departing from the scope and spirit of the invention as disclosed in the accompanying claims.

Accordingly, the scope of the present invention is not construed as being limited to the described embodiments but is defined by the appended claims as well as equivalents thereto.

What is claimed is:

1. A current driving circuit, comprising:
a plurality of channel circuits that include a first transistor into which the input current flows, a second transistor generating the output current by mirroring the input current, a plurality of switches connected between the first and second transistors in parallel and optionally connecting electrically the first and second transistors in response to the control signals, and a controller optionally activating the control signals each corresponding to the switches according to the magnitude of the input current;
an adder that adds output current of the channel circuits to generate driving current.

2. The current driving circuit according to claim 1, wherein the switches have different channel sizes.

3. The current driving circuit according to claim 2, wherein the controller activates any one of the control signals according to the magnitude of the input current.

4. The current driving circuit according to claim 2, wherein the controller activates control signals corresponding to a switch having a larger channel size as the magnitude of the input current becomes large and activates control signals corresponding to a switch having a smaller channel size as the magnitude of the input current becomes small.

5. The current driving circuit according to claim 1, wherein the switches have the same channel size.

6. The current driving circuit according to claim 5, wherein the controller activates at least one of the control signals according to the magnitude of the input current.

7. The current driving circuit according to claim 5, wherein the controller activates a larger number of control signals as the magnitude of the input current becomes large and activates a smaller number of control signals as the magnitude of the input current becomes small.

8. A light storage system, comprising:
a current driving circuit including a plurality of channel circuits that include a first transistor into which the input current flows, a second transistor generating the output current by mirroring the input current, a plurality of switches connected between the first and second transistors in parallel and optionally connecting electrically the first and second transistors by the control signals and optionally activates the switches according to the magnitude of the input current and adds output current from the channel circuits and outputs them to the driving current; and
an optical pickup unit that emits light to an optical disc to record information on the optical disc or detects the recorded information and controls the intensity of light according to the driving current.

9. The light storage system according to claim 8, wherein the switches have different channel sizes.

10. The light storage system according to claim 9, wherein the current driving circuit selects a switch having a larger channel size as the magnitude of the input current becomes large to electrically connect between the first and second transistors by the selected switch.

11. The light storage system according to claim 8, wherein the switches have the same channel size.

12. The light storage system according to claim 11, wherein the current driving circuit selects a larger number of switches as the magnitude of the input current becomes large and electrically connects between the first and second transistors by the switch.
